(19) United States
(12) Patent Application Publication
(10) Pub. No.: US 2014/0034103 A1
(43) Pub. Date: Feb. 6, 2014

(54) SYSTEM, METHODS, AND DEVICES FOR GENERATING POWER USING A THERMOELECTRIC DEVICE WITH CLOSED LOOP COOLING SYSTEM FOR MOBILE DEVICE AND BATTERY CHARGING

(71) Applicants: Benjamin Michael Kellie, Lompoc, CA (US); Adam Lucas Millat, Dayton, OH (US); Yuri Jacques Kubo, Lompoc, CA (US)

(72) Inventors: Benjamin Michael Kellie, Lompoc, CA (US); Adam Lucas Millat, Dayton, OH (US); Yuri Jacques Kubo, Lompoc, CA (US)

(73) Assignee: STAMP TEG LLC, Dayton, OH (US)

(21) Appl. No.: 13/954,900

(22) Filed: Jul. 30, 2013

Related U.S. Application Data
(60) Provisional application No. 61/677,949, filed on Jul. 31, 2012.

(51) Int. Cl. H01L 35/32

(52) U.S. Cl. CPC H01L 35/32
USPC 136/201; 136/205; 136/206

(57) ABSTRACT

The pending disclosure describes systems, methods, and devices for generating power using a thermoelectric device. Such systems, methods, and devices may include one or more heat pipes containing a fluid. Moreover, each of the heat pipes may be coupled to the top surface of one or more thermoelectric modules. Also, a heat sink may be coupled to the top end of the one or more heat pipes. Further, a charging circuit may be coupled to the one or more thermoelectric modules. Moreover, the bottom surface of the one or more thermoelectric modules may be heated from an external heat source to a temperature higher than the temperature of the top surface of the one or more thermoelectric modules thereby generating voltage to be provided to the electric charging circuit.

### CROSS-REFERENCE TO RELATED APPLICATIONS

The present application is related to and claims benefit under 35 U.S.C. §119(e) and the laws and rules of the United States from U.S. Provisional Patent Application Ser. No. 61/677,949 filed on Jul. 31, 2012 the entire contents of which are being incorporated herein by reference.

### BACKGROUND OF THE INVENTION

In the current state of the art, users of mobile devices such as mobile phones and global position system (GPS) devices as well as tablet computers and laptop computers are regularly monitoring their remaining power (e.g. battery life). Further, as the remaining power (e.g. battery life dwindles below a threshold), users must seek a power source (e.g. an electrical outlet or another device (i.e. a laptop computer to charge a mobile phone)) such that users can recharge their mobile devices to continue using them. However, there are many times a user may need to recharge their mobile device but is without a charger or adapter to access the external power source. Alternatively, a user may have a charger or adapter but no available external source (e.g. electrical outlet) from which to access power. Further, many users utilize their mobile devices while staying outdoors (e.g. camping, bike riding, hiking, etc.) and may need to recharge their mobile devices with no suitable power source available.

Accordingly, there is a need for systems, methods, and devices for generating power for mobile devices using a thermoelectric device.

### BRIEF DESCRIPTION OF THE SEVERAL VIEWS OF THE DRAWINGS

The accompanying figures, where like reference numerals refer to identical or functionally similar elements throughout the separate views, together with the detailed description below, are incorporated in and form part of the specification, and serve to further illustrate embodiments of concepts that include the claimed invention, and explain various principles and advantages of those embodiments.

FIG. 1 is a block diagram of an example thermoelectric device in accordance with some embodiments.

FIG. 2 is another block diagram of an example thermoelectric device in accordance with some embodiments.

FIG. 3 is another block diagram of an example thermoelectric device in accordance with some embodiments.

FIG. 4 is a block diagram of an example charging circuit coupled to a thermoelectric device in accordance with some embodiments.

FIG. 5 is a flowchart of an example method of generating power using a thermoelectric device in accordance with some embodiments.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

The apparatus and method components have been represented where appropriate by conventional symbols in the drawings, showing only those specific details that are pertinent to understanding the embodiments of the present invention so as not to obscure the disclosure with details that will be readily apparent to those of ordinary skill in the art having the benefit of the description herein.

### DETAILED DESCRIPTION OF THE INVENTION

The pending disclosure describes systems, methods, and devices for generating power or voltage using a thermoelectric device. Such systems, methods, and devices may include a housing (i.e. a chassis) as well as one or more thermoelectric modules coupled to the housing. Further, each of the one or more thermoelectric modules may have a bottom surface and a top surface. In addition, the systems, methods, and devices may include one or more heat pipes containing a fluid. Moreover, each of the heat pipes may have a bottom end and a top end, the bottom end of the one or more heat pipes is coupled to the top surface of one or more thermoelectric modules. Also, a heat sink may be coupled to the top end of the one or more heat pipes and the housing. Further, a charging circuit may be coupled to the one or more thermoelectric modules. Moreover, the bottom surface of the one or more thermoelectric modules may be heated from an external heat source to a temperature higher than the temperature of the top surface of the one or more thermoelectric modules thereby developing an electric potential within the device based on the bottom surface of the thermoelectric modules being at a higher temperature than the temperature of the top surface of the thermoelectric modules, thereby generating voltage to be provided to the electric charging circuit.

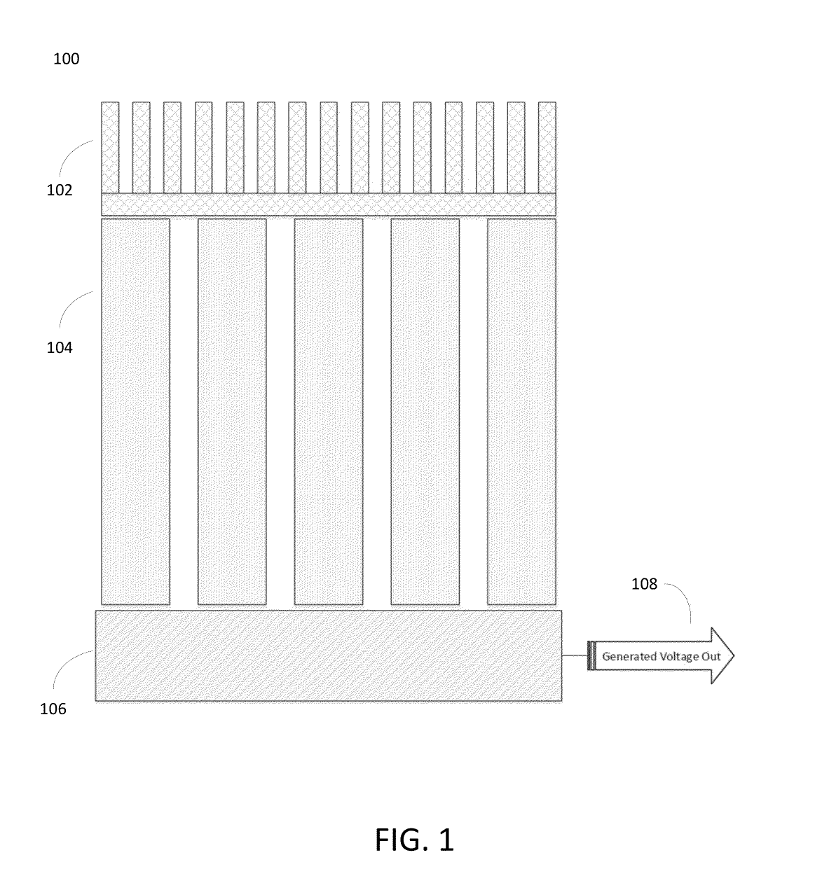

FIG. 1 is a block diagram of an example thermoelectric device 100 in accordance with some embodiments. The example thermoelectric device 100 may include one or more thermoelectric modules 106 (also called thermoelectric generators or thermopiles), one or more heat pipes 104, and a heat sink 102 all of which may be encased in a housing (not shown) such that the thermoelectric modules 106 are coupled to the housing. Further, the thermoelectric modules 106 have a bottom surface and a top surface. The bottom surface is coupled to the housing and the top surface is coupled to the heat pipes 104. In addition, each of the heat pipes 104 have a bottom end coupled to the top surface of the thermoelectric modules 106 and each of the heat pipes 104 have a top end coupled to the heat sink 102. The one or more heat pipes 104 contains a fluid such as, but not limited to, water, isopropyl alcohol, or any other known fluid in the art. Moreover, the thermoelectric device may include a charging circuit coupled (not shown) to the one or more thermoelectric modules 106.

In one embodiment, the bottom surface of the one or more thermoelectric modules 106 is heated from an external heat source to a temperature higher than the temperature of the top surface of the one or more thermoelectric modules 106 thereby developing an electric potential within the thermoelectric device 102 based on the bottom surface of the thermoelectric modules 106 being at a higher temperature than the temperature of the top surface of the thermoelectric modules 106, generating voltage to be provided to a charging circuit 108.

Further, as the external heat source provides heat to the bottom of the thermoelectric device 100, not only is the bottom surface of the thermoelectric modules 106 heated but also the top surface of the thermoelectric modules 106. Moreover, the fluid (which may be initially in a liquid state) contained at the bottom ends of the one or more heat pipes 104 is also heated. The heat raises a temperature of the fluid to a boiling point (e.g. 80° C. for isopropyl alcohol, 100° C. for water). As the fluid temperature reaches the boiling point, the fluid vaporizes from a liquid into a gas and rises to the top end of each of the heat pipes 104. In addition, the fluid vapor condenses when it reaches the top end of the heat pipes 104 due the heat sink 102. That is, the heat sink 102 may be made of a thermal conducting material that carries heat away from the top end of the heat pipes into fins that provide a large surface area for the heat to dissipate out of the thermoelectric device 100.

By drawing heat away from the top end of the heat pipes 104, the heat sink 102 effectively cools the vaporized fluid below its boiling point thereby condensing the vaporized fluid from a gas back into a liquid state. The fluid flows back down to the bottom end of the heat pipes 104 having at a temperature lower than the boiling point of the fluid. Thus, the condensed fluid effectively cools the top surface of the thermoelectric modules 106 to a temperature near the temperature of the fluid thereby maintaining the top surface of the thermoelectric modules 106 at temperature lower than the bottom surface of the thermoelectric modules 106. Thus, the thermoelectric modules 106 continue to develop an electric potential within the thermoelectric device 100 (due to the temperature differential between top surface of the thermoelectric modules 106 and the bottom surface of the thermoelectric modules 106) and generates voltage to be provided to a charging circuit 108. Moreover, the electric potential is generated by causing charge carrier diffusion through a conduction band of the one or more thermoelectric modules because the bottom surface of the one or more thermoelectric modules 106 is at higher temperature than the top surface of the one or more thermoelectric modules 106. Further, the thermoelectric device 100 can be described as a closed loop system. That is, the thermoelectric device 100 uses the repeated vaporization and condensation of the fluid in the heat pipes to maintain a temperature differential between the top surface and bottom surface of the thermoelectric modules to provide voltage to the charging circuit 106.

In some embodiments, the charging circuit includes a battery charging circuit that receives voltage or charge from the one or more thermoelectric modules 106. Further, the charging circuit may include one or more charge storage devices such that the battery charging circuit provides charge to the one or more charge storage devices. Examples of the charge storage devices may be one or more batteries or one or more capacitors. In addition, the charging circuit may include a mobile device interface that is coupled to and receives charge from the battery charging circuit and the one or more charge storage devices.

In further embodiments, the thermoelectric device 100 is a portable device that may be used in various environments and outdoor settings during a camping trip or mountain bike ride, hike, during a road trip, or any environment or setting that does not have a suitable power source available to charge a mobile device (e.g. mobile phone, GPS device, tablet computer, laptop computer, etc.). Thus, the mobile device interface may be a universal serial bus (USB) interface or may be any other interface known in the art that may be used to couple to a mobile device.

Examples of the external heat source may include a variety of sources known in the art. Such examples of external heat sources may include a frying pan or hot plate over a campfire or grill. Other examples of external heat sources may include a hood of a running or recently running vehicle or an asphalt road warmed by the sun. A further example of an external heat source may be sunlight concentrated through a Fresnel lens (or any other lens or magnifying glass) that provides heat to the bottom surface of the thermoelectric modules 106.

Further embodiments of the thermoelectric device 100 may be used in electric grid applications. For example, the thermoelectric device 100 may be incorporated by an electric utility company at a power generation station to generate and provide power to the electric company's customers. In such embodiments, the charging circuit may include an electric grid interface instead of the mobile device interface to provide power from the thermoelectric device 100 to the electric grid and in turn various electric company customers.

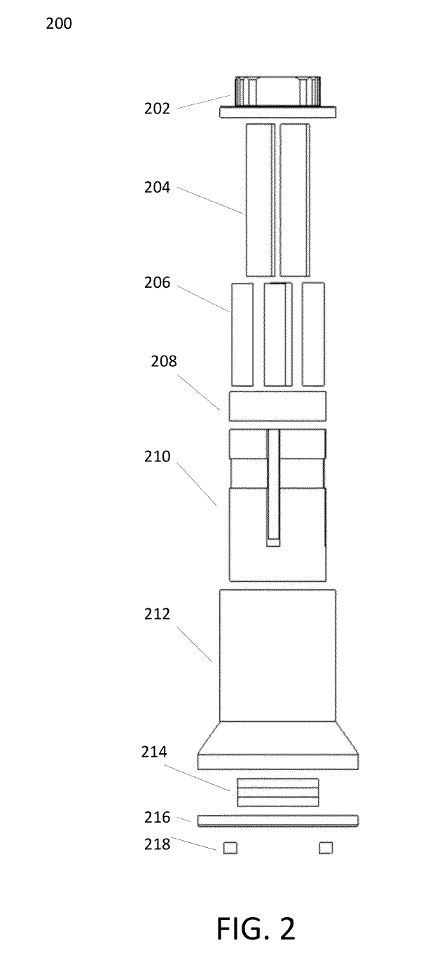

FIG. 2 is another block diagram of an example thermoelectric device 200 in accordance with some embodiments. The thermoelectric device 200 includes a heat sink 202 coupled to one or more heat pipes 204. Moreover, the heat pipes 204 contain a fluid such as, but not limited to, water, isopropyl alcohol, or any other known fluid in the art. Further, the thermoelectric device 200 includes one or more rechargeable batteries 206. In addition, the thermoelectric device 200 includes charging circuit and control electronics 208 flexibly mounted within the thermoelectric device 200. The rechargeable batteries 206 are coupled to the charging circuit 206 and act as charge storage devices. Moreover, the thermoelectric device 200 includes a component barrel 210 that packages or houses internal components such as the rechargeable batteries 206 and the heat pipes 204. Further, the thermoelectric device 200 includes a chassis 212 (or housing) that houses the component barrel 210 (and the contents therein) and the charging circuit and control electronics 208. In addition, the chassis 212 houses the one or more thermoelectric modules 214. Moreover, the chassis 212 is coupled to the conduction plate 216. Further, the conduction plate 216 may be coupled to the chassis 212 and one or more magnets 218 that can be coupled to an external heat source.

In one embodiment, the thermoelectric device 200 may be coupled to an external heat source (e.g. frying pan, hot plate, hood of a running or idling vehicle, etc.) using the one or more magnets 218. The conduction plate 216 is made of thermal conducting material that allows heat received from the external heat source to be passed to the bottom surface of the thermoelectric modules 214. Further, as the external heat source provides heat to the thermoelectric device 200, not only is the bottom surface of the thermoelectric modules 214 heated but also the top surface of the thermoelectric modules 214. Moreover, the fluid (which is initially in a liquid state) resting at the bottom ends of the one or more heat pipes 204 is also heated. The heat raises a temperature of the fluid to a boiling point (e.g. 80° C. for isopropyl alcohol, 100° C. for water). As the fluid temperature reaches the boiling point, the fluid vaporizes from a liquid into a gas and rises to the top end of each of the heat pipes 204. In addition, the fluid vapor condenses when it reaches the top end of the heat pipes 204 due the heat sink 202. That is, the heat sink 202 may be made of a thermal conducting material that carries heat away from the top end of the heat pipes into fins that provide a large surface area for the heat to dissipate out of the thermoelectric device 200.

By drawing heat away from the top end of the heat pipes 104, the heat sink 202 effectively cools the vaporized fluid below its boiling point thereby condensing the vaporized fluid from a gas back into a liquid state. The fluid flows back down to the bottom end of the heat pipes 204 having at a temperature lower than the boiling point of the fluid. Thus, the condensed fluid effectively cools the top surface of the thermoelectric modules 214 to a temperature near the temperature of the fluid thereby maintaining the top surface of the thermoelectric modules 214 at temperature lower than the bottom surface of the thermoelectric modules 214. Thus, the thermoelectric modules 214 continues to develop an electric potential within the thermoelectric device 200 (due to the temperature differential between top surface of the thermoelectric modules 214 and the bottom surface of the thermoelectric modules 214) and generates voltage to be provided to the charging circuit. Moreover, the electric potential is generated by causing charge carrier diffusion through a conduction band of the one or more thermoelectric modules because the bottom surface of the one or more thermoelectric modules 214 is at higher temperature to the top surface the one or more thermoelectric modules 214.

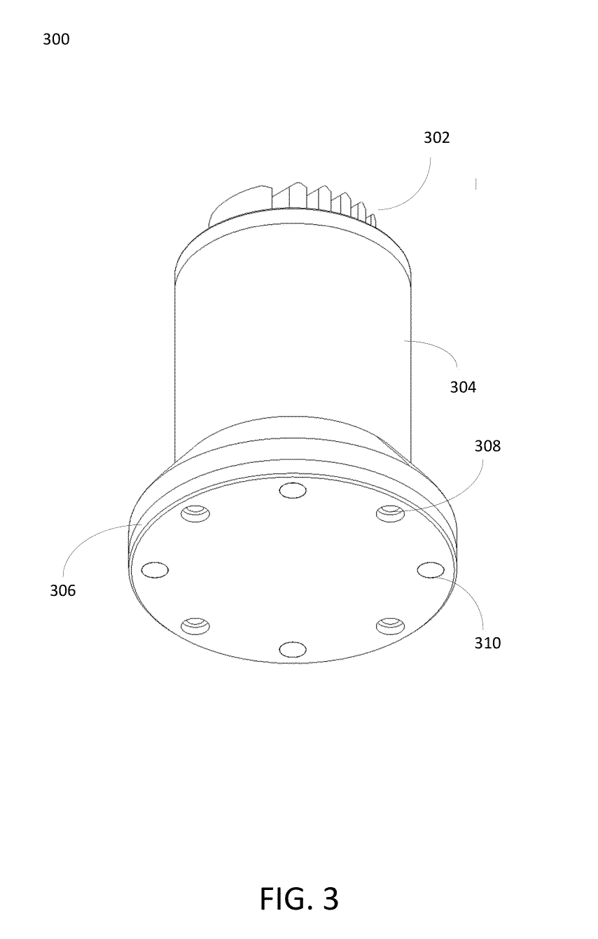

FIG. 3 is another block diagram of an example thermoelectric device 300 in accordance with some embodiments. The thermoelectric device 300 may be another view of the thermoelectric device shown in FIG. 2. That is, some of the components shown in FIG. 2 may be contained within or housed by the thermoelectric device 300 shown in FIG. 3. Further, the thermoelectric device 300 includes a heat sink 302 that may be coupled to one or more heat pipes. In addition, each of the heat pipes contains a fluid (e.g. isopropyl alcohol, water, etc.) and is coupled to one or more thermoelectric modules. The heat pipes and thermoelectric modules may be housed by a housing or chassis 304. Also, the housing or chassis 304 may contain a charging circuit coupled to the thermoelectric modules and rechargeable batteries coupled to the charging circuit. Moreover, the chassis 304 may be coupled to a conduction plate 306. Further, the bottom end of the chassis 304 may include one or more holes 308 for screws to couple the chassis 304 to the conduction plate 306. In addition, the bottom end of the chassis 304 may include magnets 310 that may be coupled to an external heat source (e.g. hot plate, frying pan, hood of a running/idling vehicle, etc.).

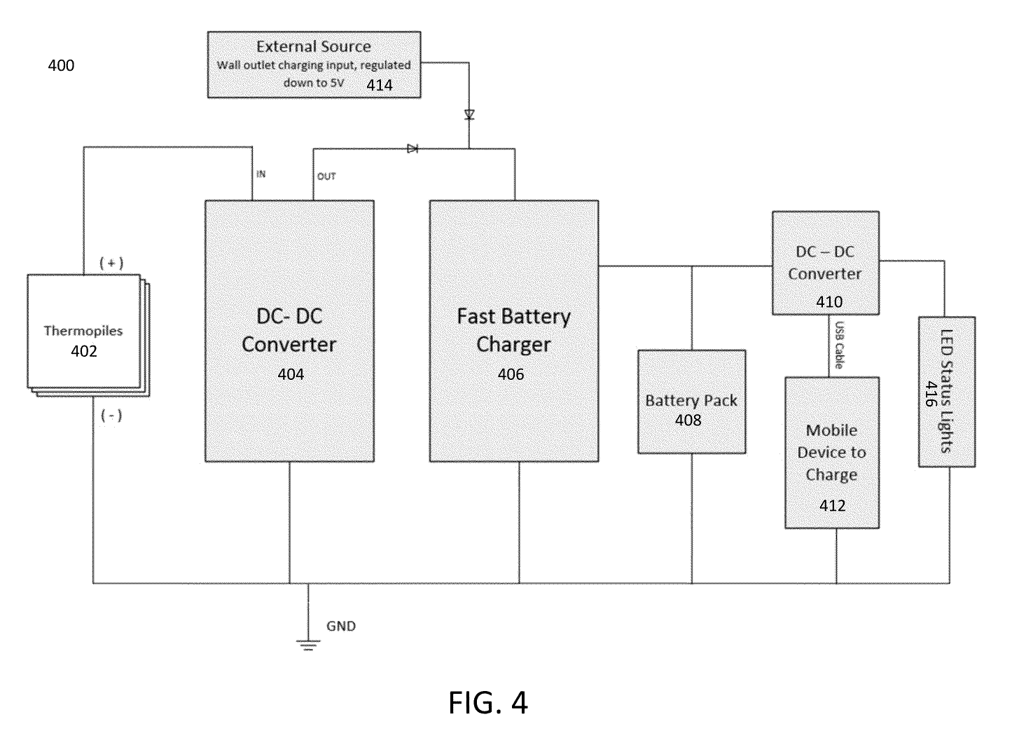

FIG. 4 is a block diagram of an example charging circuit 400 coupled to a thermoelectric device in accordance with some embodiments. The charging circuit 400 may include one or more thermoelectric modules 402. Further, the charging circuit 400 includes a first DC-to-DC converter 404 that receives charge from the one or more thermoelectric modules 402 and conditions and provides the charge to the battery charging circuit. An example of a first DC-to DC converter that may be used in the charging circuit 400 may be the Maxim 1703. The first DC-to-DC converter 404 is coupled to an external (charge or power) source 414 (e.g. electrical outlet) and a fast battery charger or battery charging circuit 406. An example fast battery charger may be the LTC 4060. In addition, the fast battery charger 406 may be also coupled to the external (charge or power) source 414. Moreover, the fast battery charger 406 is coupled to one or more charge storage devices (e.g. battery pack) 408. An example battery pack may be a NiMH four cell battery pack. Further, the charging circuit 400 includes a second DC-to-DC converter 410 coupled to the one or more charge storage devices 408 and the battery charging circuit (fast battery charger) and the mobile device 412 through a mobile device interface. The second DC-to-DC converter 410 conditions the charge to the mobile device 412 through a mobile device interface (e.g. USB interface or any device interface that can handle 5 volts). An example of a second DC-to DC converter that may be used in the charging circuit 400 may be the Maxim 1703. Further, the second DC-to-DC converter 410 is coupled to a set of LED status lights that indicate the operation or faults of the thermoelectric device.

In one embodiment, the one or more charge storing devices 408 are coupled to an external (charge or power) source interface such that the one or more charge storing devices 408 receives and stores charges from an external (charge or power) source 414 before being transported for use.

In further embodiments, the charging circuit 400 may be used with mobile devices or any devices requiring a five volts power supply

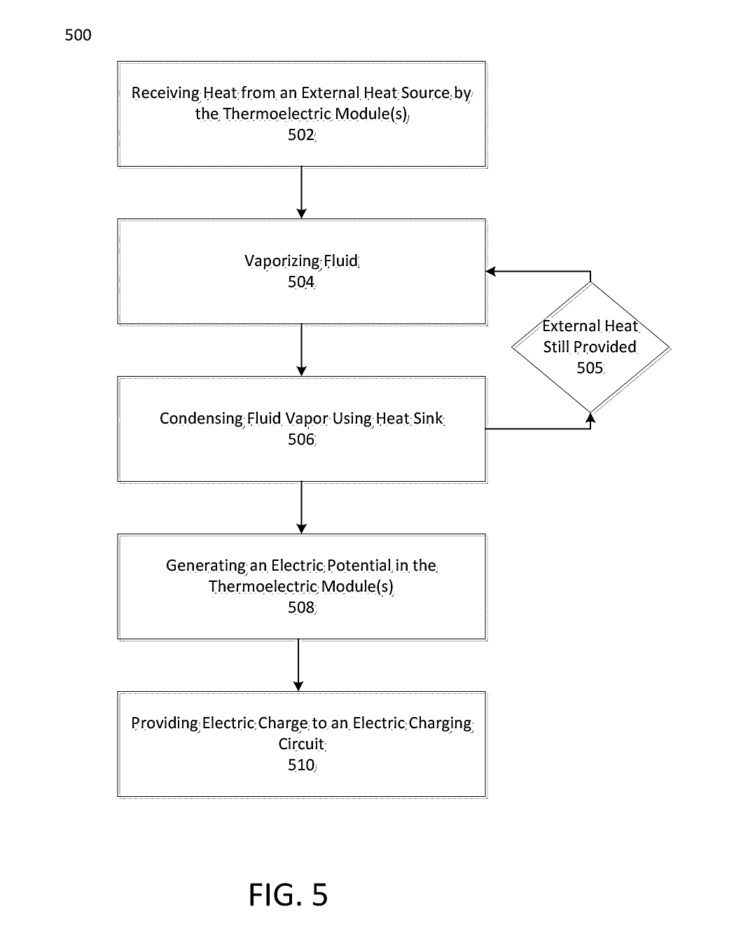

FIG. 5 is a flowchart of an example method 500 of generating power using a thermoelectric device in accordance with some embodiments. The method 500 includes receiving, by one or more thermoelectric modules, heat from an external heat source, as shown in block 502. The heat is received by the bottom surface of the one or more thermoelectric modules.

Examples of the external heat source may include a variety of sources known in the art. Such examples of external heat sources may include a frying pan or hot plate over a campfire or grill. Other examples of external heat sources may include a hood of a running or recently running vehicle or an asphalt road warmed by the sun. A further example of an external heat source may be sunlight concentrated through a Fresnel lens (or any other lens or magnifying glass) that provides heat to the bottom surface of the thermoelectric modules.

The thermoelectric device may include one or more heat pipes coupled to the top surface of thermoelectric devices. Each of the heat pipes contains a fluid (e.g. isopropyl alcohol, water, etc.) initially in a liquid state. Further, the method 500 includes vaporizing fluid (from a liquid to a gas) at a bottom end of one or more heat pipes coupled to the top surface of the one or more thermoelectric modules, as shown in block 504. That is, the external heat source not only heats the bottom surface of the thermoelectric modules but also the top surface of the thermoelectric modules, the bottom end of the heat pipes and the fluid contained therein such that the fluid increases in temperature no greater than its boiling point (80° C. for isopropyl alcohol, 100° C. for water at standard pressure—Note, boiling point change due different pressure environments) and vaporizes into a gas. Such fluid vapor rises to the top end of each of the heat pipes.

Further, a heat sink is coupled to the top end of each heat pipe. In addition, the method 500 includes condensing fluid vapor by a heat sink back into a liquid state, as shown in block 506. Thus, the fluid flows back down to the bottom end of the one or more heat pipes thereby cooling the top surface of the one or more thermoelectric modules to a temperature lower than a temperature of the bottom surface of the one or more thermoelectric modules. That is, the bottom surface of the thermoelectric modules is at or above the boiling point of the fluid and the condensed fluid is below its boiling temperature and cools the top surface of the thermoelectric modules to a temperature below the bottom surface.

Moreover, the method 500 includes generating an electric potential in the one or more thermoelectric modules based on the bottom surface of the thermoelectric modules being at a higher temperature than a temperature of the top surface of the thermoelectric modules, as shown in block 508. Further, the method includes providing, by a diffusion of charge carriers through the conduction band of the one or more thermoelectric modules, electric charge to charge a charging circuit, as shown in block 510.

Further, the condensed fluid may be vaporized again and condensed again as the external heat source provided heats the bottom surface of the thermoelectric modules and then eventually to the top surface of the thermoelectric modules, as shown in block 505. The thermoelectric device used in the example method 500 can be described as a closed loop system. That is, the thermoelectric device uses the repeated vaporization and condensation of the fluid in the heat pipes to maintain a temperature differential between the top surface and bottom surface of the thermoelectric modules to provide voltage to the charging circuit.

In some embodiments, the charging circuit includes a battery charging circuit that receives charge from the one or more thermoelectric modules and one or more charge storage devices coupled to the battery charging circuit such that the battery charging circuit provides charge to the one or more charge storage devices. Further, the one or more charge storage devices may be one or more batteries or one or more capacitors. In addition, the charging circuit includes a mobile device interface coupled to and receives charge from the battery charging circuit and the one or more charge storage devices.

Moreover, the charging circuit further includes a first DC-to-DC converter that receives charge from the one or more thermoelectric modules and conditions and provides the charge to the battery charging circuit and a second DC-to-DC converter coupled to the one or more charge storage devices and the battery charging circuit and the mobile device interface. The second DC-to-DC converter is used to condition the charge to the mobile device interface. Further embodiments of the method 500 may include the one or more charge storing devices is coupled to an external (charge or power) source interface such that the one or more charge storing devices receives and stores charges from an external (charge or power) source (e.g. electrical outlet, other electronic device, etc.) before being transported for use.

In the foregoing specification, specific embodiments have been described. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of present teachings.

The benefits, advantages, solutions to problems, and any element(s) that may cause any benefit, advantage, or solution to occur or become more pronounced are not to be construed as a critical, required, or essential features or elements of any or all the claims. The invention is defined solely by the appended claims including any amendments made during the pendency of this application and all equivalents of those claims as issued.

Moreover in this document, relational terms such as first and second, top and bottom, and the like may be used solely to distinguish one entity or action from another entity or action without necessarily requiring or implying any actual such relationship or order between such entities or actions. The terms “comprises,” “comprising,” “has”, “having,” “includes”, “including,” “contains”, “containing” or any other variation thereof, are intended to cover a non-exclusive inclusion, such that a process, method, article, or apparatus that comprises, has, includes, contains a list of elements does not include only those elements but may include other elements not expressly listed or inherent to such process, method, article, or apparatus. An element proceeded by “comprises . . . a”, “has . . . a”, “includes . . . a”, “contains . . . a” does not, without more constraints, preclude the existence of additional identical elements in the process, method, article, or apparatus that comprises, has, includes, contains the element. The terms “a” and “an” are defined as one or more unless explicitly stated otherwise herein. The terms “substantially”, “essentially”, “approximately”, “about” or any other version thereof, are defined as being close to as understood by one of ordinary skill in the art, and in one non-limiting embodiment the term is defined to be within 10%, in another embodiment within 5%, in another embodiment within 1% and in another embodiment within 0.5%. The term “coupled” as used herein is defined as connected, although not necessarily directly and not necessarily mechanically. A device or structure that is “configured” in a certain way is configured in at least that way, but may also be configured in ways that are not listed.

It will be appreciated that some embodiments may be comprised of one or more generic or specialized processors (or “processing devices”) such as microprocessors, digital signal processors, customized processors and field programmable gate arrays (FPGAs) and unique stored program instructions (including both software and firmware) that control the one or more processors to implement, in conjunction with certain non-processor circuits, some, most, or all of the functions of the method and/or apparatus described herein. Alternatively, some or all functions could be implemented by a state machine that has no stored program instructions, or in one or more application specific integrated circuits (ASICs), in which each function or some combinations of certain of the functions are implemented as custom logic. Of course, a combination of the two approaches could be used.

Moreover, an embodiment can be implemented as a computer-readable storage medium having computer readable code stored thereon for programming a computer (e.g., comprising a processor) to perform a method as described and claimed herein. Examples of such computer-readable storage mediums include, but are not limited to, a hard disk, a CD-ROM, an optical storage device, a magnetic storage device, a ROM (Read Only Memory), a PROM (Programmable Read Only Memory), an EPROM (Erasable Programmable Read Only Memory), an EEPROM (Electrically Erasable Programmable Read Only Memory) and a Flash memory. Further, it is expected that one of ordinary skill, notwithstanding possibly significant effort and many design choices motivated by, for example, available time, current technology, and economic considerations, when guided by the concepts and principles disclosed herein will be readily capable of generating such software instructions and programs and ICs with minimal experimentation.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus the following claims are hereby incorporated into the Detailed Description, with each claim standing on its own as a separately claimed subject matter.

We claim:

1. A device comprising,
a housing;
one or more thermoelectric modules coupled to the housing, each of the one or more thermoelectric modules having a bottom surface and a top surface;
one or more heat pipes containing a fluid, each of the heat pipes having a bottom end and a top end, the bottom end of the one or more heat pipes coupled to the top surface of one or more thermoelectric modules;
a heat sink coupled to the top end of the one or more heat pipes and the housing;
a charging circuit coupled to the one or more thermoelectric modules;
wherein the bottom surface of the one or more thermoelectric modules is heated from an external heat source to a temperature higher than the temperature of the top surface of the one or more thermoelectric modules thereby developing an electric potential within the device based on the bottom surface of the thermoelectric modules being at a higher temperature than the temperature of the top surface of the thermoelectric modules, generating voltage to be provided to the charging circuit.

2. The device of claim 1, wherein the charging circuit includes:
a battery charging circuit that receives charge from the one or more thermoelectric modules;
one or more charge storage devices coupled to the battery charging circuit such that the battery charging circuit provides charge to the one or more charge storage devices.

3. The device of claim 2, wherein the charging circuit includes:
a mobile device interface that is coupled to and receives charge from the battery charging circuit and the one or more charge storage devices.

4. The device of claim 2, wherein the one or more charge storage devices is selected from the group consisting of one or more batteries and one or more capacitors.

5. The device of claim 2, wherein the charging circuit further includes:
a first DC-to-DC converter that receives charge from the one or more thermoelectric modules and conditions and provides the charge to the battery charging circuit;
a second DC-to-DC converter coupled to the one or more charge storage devices and the battery charging circuit and the mobile device interface, the second DC-to-DC converter conditions the charge to the mobile device interface.

6. The device of claim 1, wherein:
the top surface of the one or more thermoelectric modules receives heat from the external heat source thereby heating the fluid at the bottom end of the one or more heat pipes coupled to the top surface of the one or more thermoelectric modules;
the fluid vaporizes and rises to the top end of the one or more heat pipes, the top end of the one or more heat pipes is coupled to the heat sink;
the heat sink condenses fluid vapor to fluid such that fluid moves to the bottom end of the one or more heat pipes coupled to the top surface of the thermoelectric modules and cooling the top surface of the thermoelectric modules to a temperature lower than the bottom surface of the thermoelectric modules thereby maintaining that the bottom surface of the thermoelectric modules is at a higher temperature than the temperature of the top surface of the one or more thermoelectric modules to maintain a necessary temperature difference for power generation and provide charge to the electric charging circuit.

7. The device of claim 1, wherein the fluid is isopropyl alcohol.

8. The device of claim 1, wherein the fluid is water.

9. The device of claim 2, wherein the one or more charge storing devices is coupled to an external source interface such that the one or more charge storing devices receives and stores charges from an external source.

10. The device of the claim 1, wherein the external heat source is sunlight concentrated through an attached Fresnel lens that provides heat to the bottom surface of the thermoelectric modules.

11. The device of claim 1 wherein the electric potential is generated by causing charge carrier diffusion through a conduction band of the one or more thermoelectric modules with the bottom surface of the one or more thermoelectric modules at higher temperature to the top surface the one or more thermoelectric modules at lower temperature.

12. A method comprising:
receiving, by one or more thermoelectric modules, heat from an external heat source wherein the heat is received by the bottom surface of the one or more thermoelectric modules;
vaporizing fluid at a bottom end of one or more heat pipes coupled to the top surface of the one or more thermoelectric modules;
condensing fluid vapor by a heat sink coupled to a top end of the one or more heat pipes thereby having the fluid flow back down to the bottom end of the one or more heat pipes cooling the top surface of the one or more thermoelectric modules to a temperature lower than a temperature of the bottom surface of the one or more thermoelectric modules;
generating an electric potential in the one or more thermoelectric modules based on the bottom surface of the thermoelectric modules being at a higher temperature than a temperature of the top surface of the thermoelectric modules;
providing, by a diffusion of charge carriers through the conduction band of the one or more thermoelectric modules, electric charge to a charging circuit.

13. The method of claim 12, wherein the charging circuit includes:
a battery charging circuit that receives charge from the one or more thermoelectric modules;
one or more charge storage devices coupled to the battery charging circuit such that the battery charging circuit provides charge to the one or more charge storage devices.

14. The method of claim 13, wherein the charging circuit includes:
a mobile device interface coupled to and receives charge from the battery charging circuit and the one or more charge storage devices.

15. The method of claim 13, wherein the one or more charge storage devices is selected from the group consisting of one or more batteries and one or more capacitors.

16. The method of claim 13, wherein the charging circuit further includes:
a first DC-to-DC converter that receives charge from the one or more thermoelectric modules and conditions and provides the charge to the battery charging circuit;
a second DC-to-DC converter coupled to the one or more charge storage devices and the battery charging circuit and the mobile device interface, the second DC-to-DC converter conditions the charge to the mobile device interface.

17. The method of claim 12, wherein the fluid is isopropyl alcohol.

18. The method of claim 12, wherein the fluid is water.

19. The method of claim 12, wherein the one or more charge storing devices is coupled to an external source interface such that the one or more charge storing devices receives and stores charges from an external source.

20. The method of the claim 12, wherein the external heat source is a Fresnel lens that provides heat to the bottom surface of the thermoelectric modules by concentrating direct sunlight.
